(19) United States
(12) Patent Application Publication
(10) Pub. No.: US 2022/0206382 A1
(43) Pub. Date: Jun. 30, 2022

(54) PATTERN FORMATION METHOD AND TEMPLATE MANUFACTURING METHOD

(71) Applicant: KIOXIA CORPORATION, Tokyo (JP)

(72) Inventors: Noriko SAKURAI, Yokohama Kanagawa (JP); Takeharu MOTOKAWA, Zushi Kanagawa (JP); Ryu KOMATSU, Atsugi Kanagawa (JP); Hideaki SAKURAI, Kawasaki Kanagawa (JP)

(21) Appl. No.: 17/463,435

(22) Filed: Aug. 31, 2021

(30) Foreign Application Priority Data
Dec. 24, 2020 (JP) 2020-214495

(51) Int. Cl. G03F 7/00; G03F 1/50; G03F 1/80

(52) U.S. Cl. CPC G03F 7/0002; G03F 1/80; G03F 1/50

(57) ABSTRACT

According to one embodiment, a pattern formation method includes patterning a first film on a substate to have a plurality of lines extending in a first direction and a second pattern portion extending in a second direction intersecting the first direction. Each line having at least a first width and being spaced from an adjacent line in the second direction by a least three times the first width and spaced from ends of the lines in the first direction by twice or less the first width. A conformal film is then formed on the patterned first film. The conformal film having a thickness equal to the first width. The patterned first film is then removed while leaving portions of the conformal film that were previously on sidewalls of the plurality of lines behind.

### CROSS-REFERENCE TO RELATED APPLICATION(S)

This application is based upon and claims the benefit of priority from Japanese Patent Application No. 2020-214495, filed Dec. 24, 2020, the entire contents of which are incorporated herein by reference.

### FIELD

Embodiments described herein relate generally to a pattern formation method and an imprint template manufacturing method.

### BACKGROUND

A technique for manufacturing a template to be used in a nanoimprint lithography method using a side wall transfer process is known.

### BRIEF DESCRIPTION OF THE DRAWINGS

FIGS. 1A and 1B show aspects related to a pattern formation method according to a first embodiment.

FIGS. 2A and 2B show aspects related to a pattern formation method according to a first embodiment.

FIGS. 3A and 3B show aspects related to a pattern formation method according to a first embodiment.

FIGS. 4A and 4B show aspects related to a pattern formation method according to a first embodiment.

FIGS. 5A and 5B show aspects of a pattern formation method of a comparison example.

FIGS. 6A and 6B show aspects of a pattern formation method of a comparison example.

FIGS. 7A and 7B show aspects of a pattern formation method of a comparison example.

FIGS. 8A and 8B show aspects of a pattern formation method of a comparison example.

FIGS. 9A and 9B show aspects related to a pattern formation method according to a second embodiment.

FIGS. 10A and 10B show aspects related to a pattern formation method according to a second embodiment.

FIGS. 11A and 11B show aspects related to a pattern formation method according to a second embodiment.

FIGS. 12A and 12B show aspects related to a pattern formation method according to a second embodiment.

FIG. 13 is an enlarged view showing a positional relationship between line patterns and a dummy pattern according to a second embodiment.

FIGS. 14A and 14B show configurations of a template according to a third embodiment.

FIGS. 15A to 15D show a template manufacturing method according to a third embodiment.

### DETAILED DESCRIPTION

Embodiments provide a pattern formation method capable of facilitating formation of a line-and-space pattern using a side wall transfer process.

In general, according to one embodiment, a pattern formation method includes: patterning a first film to have a pattern including a plurality of line that extend in a first direction, each line having at least a first width and being spaced from an adjacent line in the plurality of lines in a second direction crossing the first direction by at least three times the first width. The pattern also including a second pattern portion that is adjacent to end portions of the plurality lines at a distance in the first direction equal to or less than twice the first width. A conformal film having a thickness equal to the first width is then formed a on side surfaces of the pattern formed in the first film. The patterned first film is then removed.

Embodiments of the disclosure will be described with reference to the drawings. In the drawings, the same or substantially similar aspects or components are denoted by same reference symbols. However, the drawings are schematic and the depicted relationships between thicknesses and planar dimensions and the like generally differ from relationships dimensions in actual use.

In the present disclosure, it is assumed that “a side wall transfer process” refers to a process of covering a core material formed using a lithography technique with a covering film, performing etching in such a manner as to remove portions of this covering film such that portions of the covering film adjoining a side wall of the core material still remain, removing the core material and transferring a pattern of the remaining portions of the covering film into a film to be processed using the remaining portions as a mask.

### First Embodiment

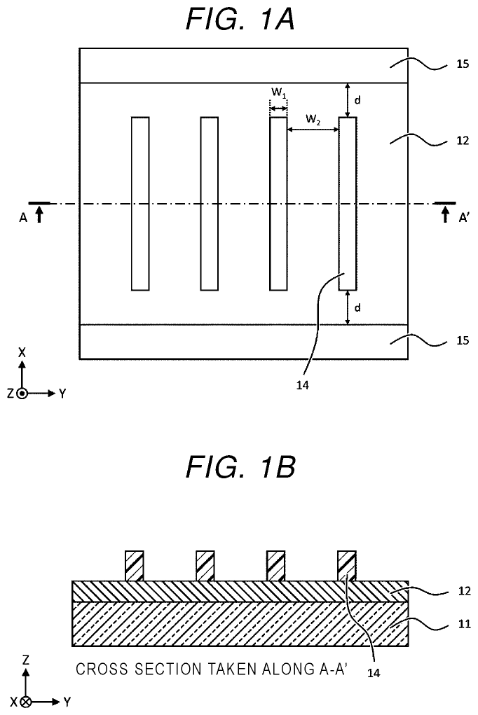

A pattern formation method according to a first embodiment will first be described with reference to FIGS. 1A to 4B. FIGS. 1A to 4B show the pattern formation method according to the first embodiment. FIGS. 1A, 2A, 3A, and 4A are plan views viewed from a Z direction. FIGS. 1B, 2B, 3B, and 4B are cross-sectional views taken along AA′ of FIGS. 1A, 2A, 3A, and 4A and viewed from an X direction.

First, a hard mask film 12 is formed on a substrate 11. The substrate 11 comprises quartz, for example. The hard mask film 12 comprises, for example, chromium.

Next, a resist film having line patterns 14 and dummy patterns 15 is formed on the hard mask film 12. The line patterns 14 and the dummy patterns 15 are formed by, for example, coating a resist on the hard mask film 12 using a spin coating method, drawing patterns on the resist film, and baking and then developing the resist to form the patterns. Examples of the resist in this context include an electron beam resist. In a case of using the electron beam resist, pattern drawing is performed by an electron beam. At this time, the dummy patterns 15 are formed in the vicinity of end portions of the line patterns 14. The line patterns 14 eventually serve as a core material in a side wall process. Part of the hard mask film 12 is exposed by removal of the resist in the patterning process.

The line patterns 14 and the dummy patterns 15 according to the first embodiment will be described. The line patterns 14 are a plurality of line patterns. Each line pattern 14 extends in the X direction and the line patterns 14 are spaced apart from one another in a Y direction. The dummy patterns 15 extend in the Y direction and are spaced apart from the line patterns 14 in the X direction. When designing to form the line patterns 14 to be identical in width and interval for the side wall transfer process, a ratio of a width W₁ of each line pattern 14 in the Y direction to a width W₂ between the line patterns 14 adjacent in the Y direction is desirably 1:3. While the case of designing to form the line patterns 14 to be identical in width and interval for the side wall transfer process is described in the present embodiment, the present disclosure is also applicable to the other cases.

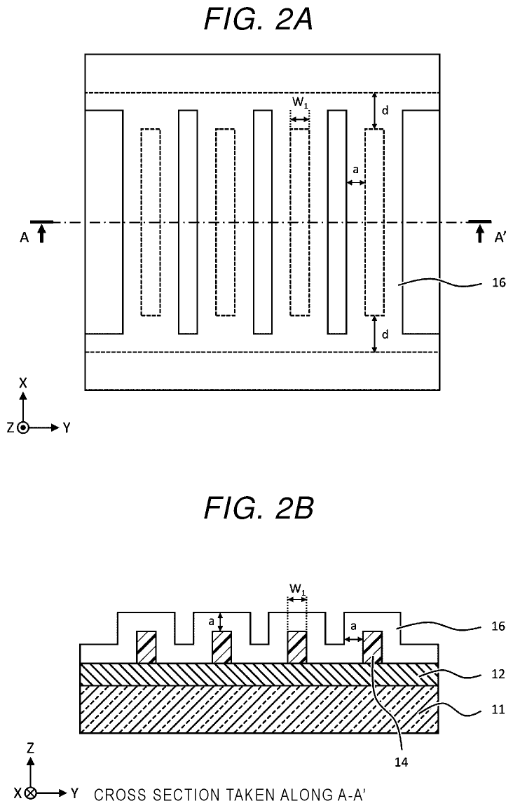

Each dummy pattern 15 is provided at a position at which a distance d between the end portion of each line pattern 14 in the X direction and the dummy pattern 15 is equal to or less than a twice the thickness a (2×thickness a) of the covering film 16 (see FIG. 2B). In this way, a stacked structure shown in FIGS. 1A and 1B is formed on the substrate 11.

Next, as shown in FIGS. 2A and 2B, the conformal covering film 16 with the thickness a is formed on upper and side surfaces of the resist film and an upper surface of the exposed part of the hard mask film 12. The covering film 16 is formed using, for example, an Atomic Layer Deposition (ALD) method or a Molecular Layer Deposition (MLD) method. The covering film 16 comprises, for example, silicon oxide. In the case of designing to form the line patterns 14 identical in width and interval by the side wall transfer process, a ratio of the width W₁ of each line pattern 14 in the Y direction to the thickness a of the covering film 16 is desirably 1:1. As described above, each dummy pattern 15 is provided at the position at which the distance d is equal to or less than the twice the thickness a of the covering film 16. Owing to this, as shown in FIGS. 2A and 2B, the covering film 16 is fills in the space between the end portions of the line patterns 14 and the dummy patterns 15.

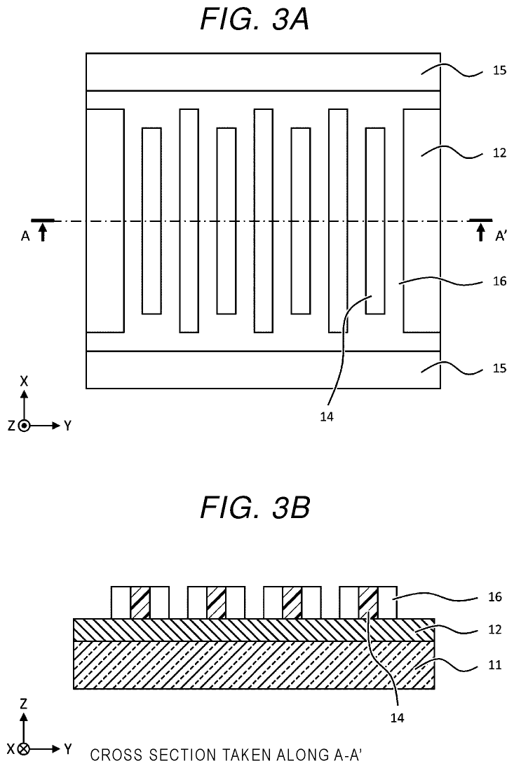

Next, the covering film 16 is etched until the upper surface of the resist film (that forms the line patterns 14 and the dummy patterns 15) is exposed. The covering film 16 is etched by, for example, an anisotropic dry etching method using trifluoromethane (CHF₃). As a result, as shown in FIGS. 3A and 3B, portions of the covering film 16 deposited on the side surfaces of the line patterns 14 and the dummy patterns 15 as well as those between the line patterns 14 and the dummy patterns 15 still remain after the etching process.

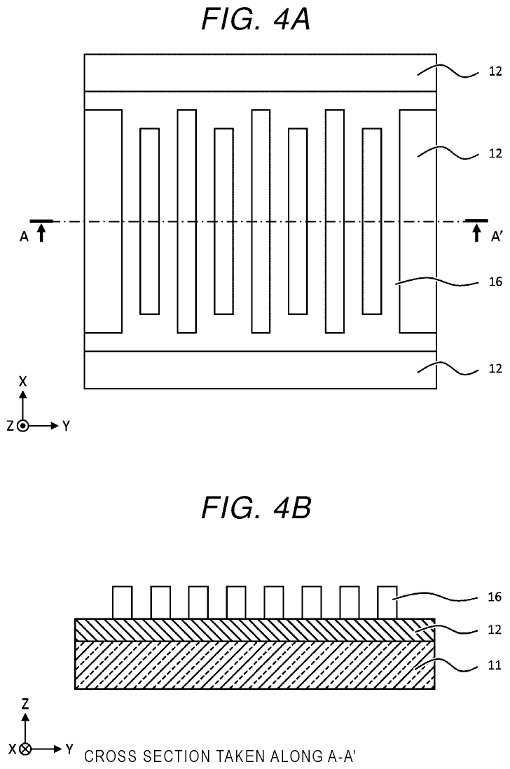

Next, as shown in FIGS. 4A and 4B, the resist film forming the line patterns 14 and the dummy patterns 15 is removed. The resist film is removed by, for example, a dry etching method using oxygen plasma. As a result, a pattern including the just the remaining portions of the covering film 16 is formed. In the pattern formation method according to the first embodiment, the covering film 16 fills the space between the X-direction end portions of the line patterns 14 and the dummy patterns 15. Owing to this, the covering film 16 has portions continuously extending in the Y direction. It is, therefore, possible to form recessed line patterns on the covering film 16.

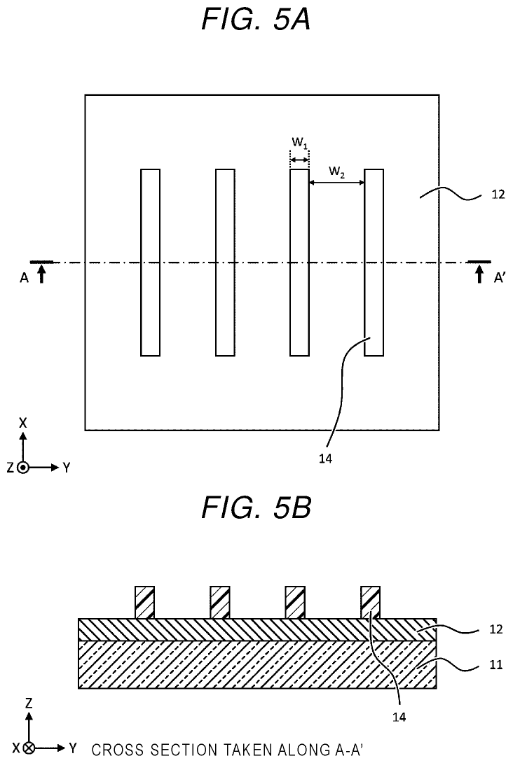

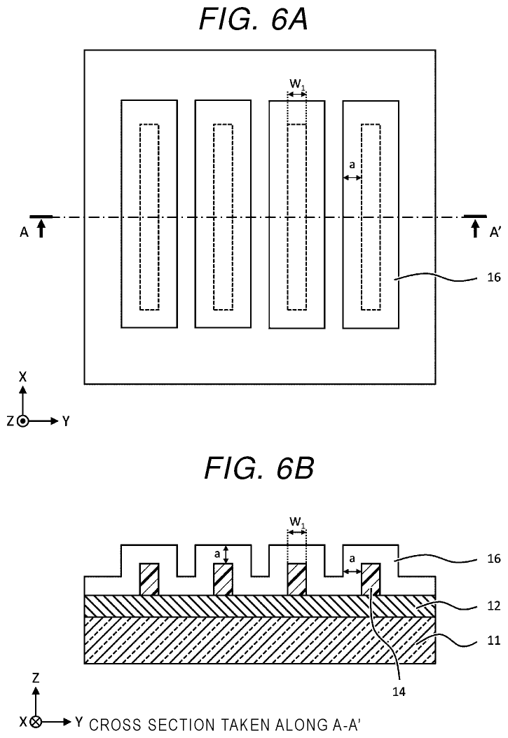

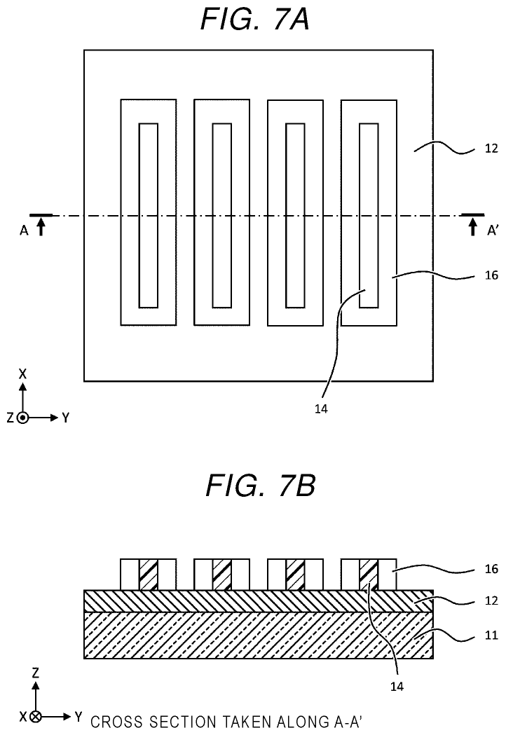

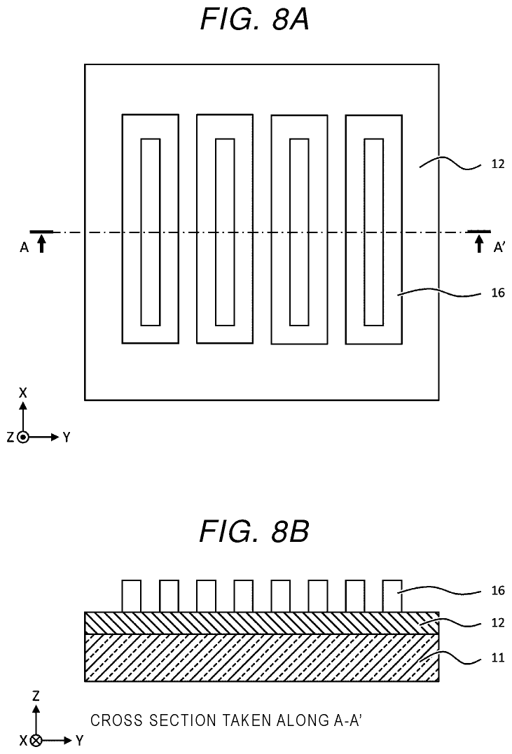

Subsequently, a pattern formation method according to a comparison example will be described with reference to FIGS. 5A to 8B. FIGS. 5A to 8B show the pattern formation method according to the comparison example. FIGS. 5A, 6A, 7A, and 8A are plan views viewed from the Z direction. FIGS. 5B, 6B, 7B, and 8B are cross-sectional views taken along AA′ of FIGS. 5A, 6A, 7A, and 8A and viewed from the X direction.

The comparison example differs from the first embodiment in that the dummy patterns 15 are not provided (as shown in FIG. 5A). The comparison example is otherwise similar to the first embodiment in the other respects.

In the pattern formation method according to the comparison example, a pattern having loop shapes at the X-direction end portions of the line patterns 14 is formed since the dummy patterns 15 are not provided (as shown in FIGS. 5A, 6A, 7A, and 8A). When a template is created with this pattern used as a mask and this pattern is transferred onto the hard mask film 12, the loop shapes remain only with raised and recessed portions of the loop shapes being inverted. To create a line-and-space pattern from this pattern, it is necessary to add processes such as forming another mask that protects portions other than the loop sections and then removing the loop sections by etching or the like.

In the pattern formation method according to the first embodiment, by contrast, the covering film 16 fills in the space between the end portions of the line patterns 14 and the dummy patterns 15 as shown in FIGS. 3A and 3B. Owing to this, unlike the comparison, shapes of portions of the covering film 16 formed in the end portions of the line patterns 14 in the X direction are not loop shapes and the portions of the covering film 16 formed in the end portions of the two line patterns 14 in the X direction are coupled to each other. Therefore, when a template is created with the pattern shown in FIGS. 4A and 4B used as a mask and the pattern is transferred onto the hard mask film 12, a line-and-space pattern without the loop shapes is formed. In this way, the pattern formation method according to the first embodiment makes it possible to facilitate forming the line-and-space pattern without having to add processing for removal of the loop shapes otherwise formed using the side wall transfer process of the comparison example.

### Second Embodiment

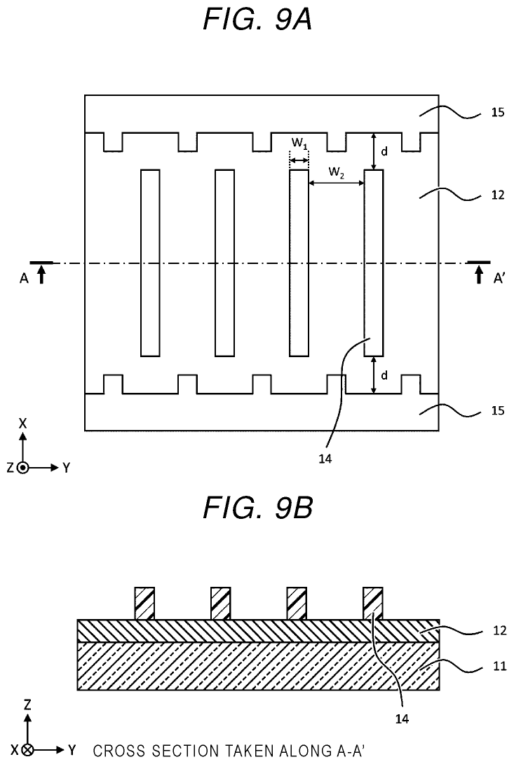

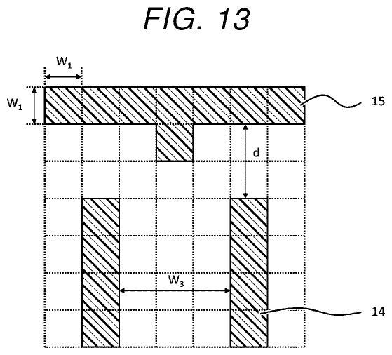

A pattern formation method according to a second embodiment will be described with reference to FIGS. 9A to 13. FIGS. 9A to 13 show the pattern formation method according to the second embodiment. FIGS. 9A, 10A, 11A, and 12A are plan views viewed from the Z direction. FIGS. 9B, 10B, 11B, and 12B are cross-sectional views taken along AA′ of FIGS. 9A, 10A, 11A, and 12A and viewed from the X direction. FIG. 13 is an enlarged view showing a positional relationship between line patterns and a dummy pattern according to the second embodiment.

The second embodiment differs from the first embodiment in that projections are provided on the dummy patterns 15. The second embodiment is otherwise similar to the first embodiment in other respects. While designing to form the line patterns 14 identical in width and interval by a side wall transfer process is described in the second embodiment, the present disclosure is also applicable to the other cases.

First, as shown in FIGS. 9A and 9B, the hard mask film 12 is formed on the substrate 11. The substrate 11 comprises, for example, quartz. The hard mask film 12 comprises, for example, chromium.

Next, the resist film is formed on the hard mask film 12. The resist film is formed, for example, by coating a resist on the hard mask film 12 using a spin coating method and baking the resist. Examples of the resist include an electron beam resist.

Next, a pattern is drawn in the resist. In the case of using an electron beam resist, pattern drawing is performed by electron beam. The dummy patterns 15 are formed near the end portions of the line patterns 14 that serve as the core material in the side wall process. While setting the thickness a of the covering film 16 to be equal to width W₁ (a=W₁) is described in the second embodiment, the present disclosure is also applicable to cases other than thickness a=width W₁. The ratio of the width W₁ of each line pattern 14 in the Y direction to the width W₂ between the line patterns 14 adjacent in the Y direction is desirably 1:3. Furthermore, the distance d between the X-direction end portion of each line pattern 14 and each dummy pattern 15 is, for example, twice the width W₁, that is, the distance d is equal to or less than 2×width W₁. The dummy patterns 15 according to the second embodiment also have the projections that project in the X direction as shown in FIG. 13. Each projection has a square shape. A center line of the square shape parallel to the X direction coincides with a center line of a recess portion between adjacent line patterns 14. While the sides of the square shape are desirably set to be equal to thickness a, the second embodiment is also applicable to the other cases. In this way, a stacked structure shown in FIGS. 9A and 9B is formed on the substrate 11.

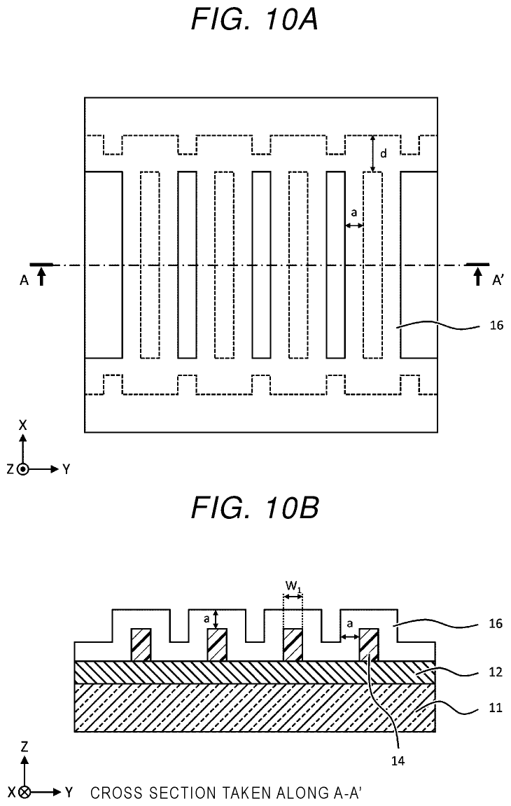

Next, as shown in FIGS. 10A and 10B, the conformal covering film 16 with the thickness a is formed on the upper and side surfaces of the resist film and the upper surface of the exposed part of the hard mask film 12. The covering film 16 is formed using, for example the ALD method or the MLD method. The covering film 16 comprises, for example, silicon oxide.

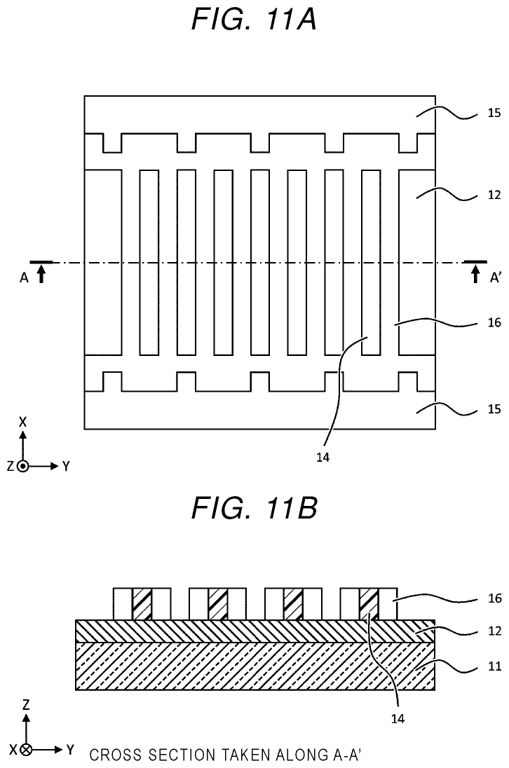

Next, the covering film 16 is etched until the upper surface of the resist film forming the line patterns 14 and the dummy patterns 15 is exposed. The covering film 16 is etched by, for example, the anisotropic dry etching method using CHF₃. As a result, as shown in FIGS. 11A and 11B, portions of the covering film 16 deposited on the side surfaces of the line patterns 14 and the dummy patterns 15 still remain after the etching.

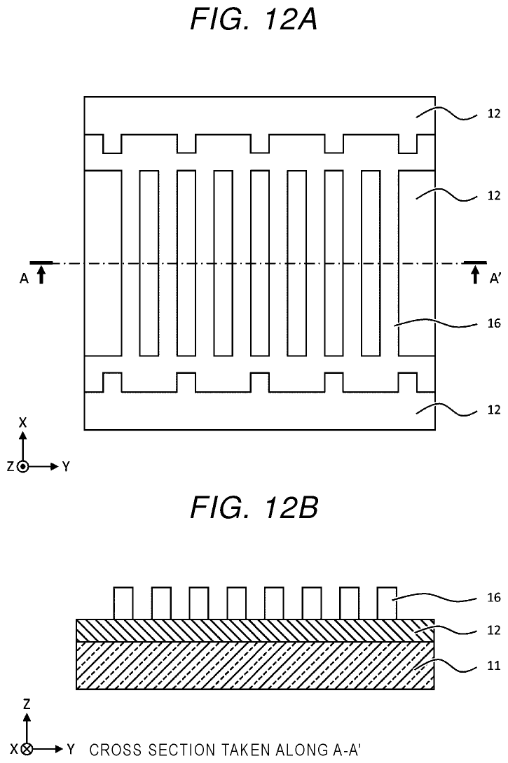

Next, as shown in FIGS. 12A and 12B, the resist film is removed. The resist film is removed by, for example, the dry etching method using oxygen plasma. As a result, a pattern including just the remaining portions of covering film 16 is formed. In the pattern formation method according to the second embodiment, the covering film 16 fills the space between the end portions of the line patterns 14 and the dummy patterns 15. Owing to this, the shapes of the portions of the covering film 16 formed in the end portions of the line patterns 14 in the X direction are not the loop shapes, and it is possible to form a pattern in which lines and spaces are inverted. Furthermore, in the pattern formation method according to the second embodiment, the square projections are provided on each dummy pattern 15. It is thereby possible to design the line-and-space pattern in such a manner as to make uniform lengths of the line-and-space pattern, as shown in FIGS. 12A and 12B, rather than the non-uniform lengths formed in the first embodiment.

### Third Embodiment

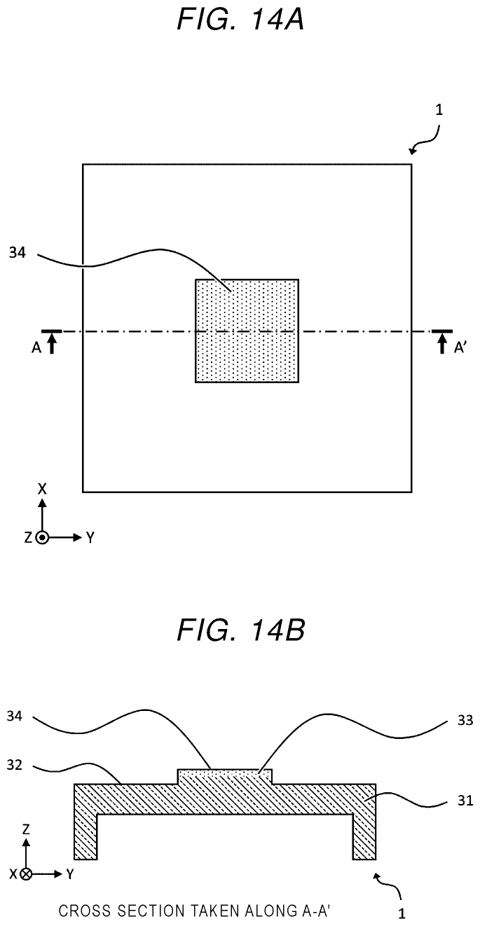

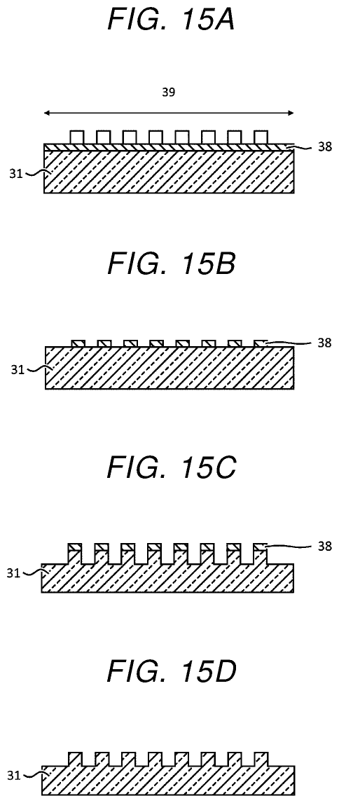

A template manufacturing method according to a third embodiment will be described with reference to FIGS. 14A to 15D. FIGS. 14A and 14B show configurations of a template according to the present embodiment. FIGS. 15A to 15D show the template manufacturing method according to the third embodiment.

First, the template according to the third embodiment will be described with reference to FIGS. 14A and 14B. FIG. 14A is a plan view of a template 1 viewed from the Z direction. FIG. 14B is a cross-sectional view of the template 1 taken along AA′ of FIG. 14A and viewed from the X direction. The template 1 is configured such that a substrate 31 of a quadrilateral shape in a view from the Z direction is processed. For nanoimprint lithography using photo-curing, the template 1 typically comprises quartz (or another transparent material).

A mesa structure 33 projecting from a principal surface 32 of the substrate 31 is provided at a center of the principal surface 32. The mesa structure 33 has a pattern surface 34. The pattern surface 34 has a recess structure (topographic pattern) formed thereon. The recess structure includes a pattern to be transferred in the nanoimprint lithography process and an alignment mark for positioning the template 1 relative to a position on the substrate being printed.

Next, the template manufacturing method according to the third embodiment will be described with reference to FIGS. 15A to 15D. As shown in FIG. 15A, a mask pattern 39 is formed by the pattern formation method as described in the first or second embodiment.

Next, as shown in FIG. 15B, a hard mask film 38 is etched using the mask pattern 39 as a mask. As a result, the mask pattern 39 is transferred into the hard mask film 38.

Next, as shown in FIG. 15C, the substrate 31 is etched using the patterned hard mask film 38 as a mask.

Next, as shown in FIG. 15D, the hard mask film 38 is removed. As a result, it is possible to create a template 1 having a pattern with small widths. The hard mask film 38 is removed by wet etching or dry etching.

The template manufacturing method according to the third embodiment uses the pattern formation method described in either one of the first or second embodiment for forming the mask pattern 39. Owing to this, it is possible to facilitate forming a line-and-space pattern using a side wall transfer process. This makes it unnecessary to perform additional pattern forming and processing steps using a resist after the side wall transfer process. Thus, it is possible to reduce the number of processes and achieve cost reduction. Additionally, a reduction in the number of required processes can contribute to improving yield.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A pattern formation method, comprising:
patterning a first film on a substate to have a plurality of lines extending in a first direction, each line having a first width and being spaced from an adjacent line in the plurality of lines in a second direction intersecting the first direction by a least three times the first width and a second pattern portion extending in the second direction and spaced from ends of the plurality of lines in the first direction by twice or less the first width;
forming a conformal film on the patterned first film, the conformal film having a thickness equal to the first width; and
removing the patterned first film while leaving portions of the conformal film that were previously on sidewalls of the plurality of lines.

2. The pattern formation method according to claim 1, wherein the adjacent lines in the plurality of lines are spaced from one another in the second direction by three times the first width.

3. The pattern formation method according to claim 1, wherein the first film is an electron beam resist.

4. The pattern formation method according to claim 1, further comprising:
transferring a pattern corresponding to the left portions of the conformal film to the substrate.

5. The pattern formation method according to claim 1, further comprising:
forming a hard mask film on the substrate before forming the first film on the substrate; and
forming the first film on the hard mask film.

6. The pattern formation method according to claim 5, wherein the hard mask film comprises at least one of chromium, molybdenum, tantalum, and carbon.

7. The pattern formation method according to claim 1, wherein the second pattern portion includes a projection portion extending in the first direction at position along the second direction that is between positions along the second direction of an adjacent pair of lines in the plurality of lines.

8. The pattern formation method according to claim 7, wherein the projection portion extends in the first direction for a distance equal to the first width.

9. The pattern formation method according to claim 1, wherein the second pattern portion includes dummy portions at both ends of each line in the plurality of lines.

10. The pattern formation method according to claim 1, wherein the conformal film is silicon oxide formed by atomic layer deposition or molecular layer deposition.

11. An imprint template manufacturing method, comprising:
patterning a first film on a substate to have a plurality of lines extending in a first direction, each line having at least a first width and being spaced from an adjacent line in the plurality of lines in a second direction intersecting the first direction by a least three times the first width and a second pattern portion extending in the second direction and spaced from ends of the plurality of lines in the first direction by twice or less the first width;
forming a conformal film on the patterned first film, the conformal film having a thickness equal to the first width;
removing the patterned first film while leaving portions of the conformal film that were previously on sidewalls of the plurality of lines; and
etching the substrate using the left portions of the conformal film as a mask.

12. The imprint template manufacturing method according to claim 11, wherein the lines in the plurality of lines are spaced from one another in the second direction by three times the first width.

13. The imprint template manufacturing method according to claim 11, wherein the first film is an electron beam resist.

14. The imprint template manufacturing method according to claim 11, wherein the substate is quartz.

15. The imprint template manufacturing method according to claim 11, further comprising:
forming a hard mask film on the substrate before forming the first film on the substrate; and
forming the first film on the hard mask film.

16. The imprint template manufacturing method according to claim 15, wherein the hard mask film comprises at least one of chromium, molybdenum, tantalum, and carbon.

17. The imprint template manufacturing method according to claim 11, wherein the second pattern portion includes a projection portion extending in the first direction at position along the second direction that is between positions along the second direction of an adjacent pair of lines in the plurality of lines.

18. The imprint template manufacturing method according to claim 17, wherein the projection portion extends in the first direction for a distance equal to the first width.

19. The imprint template manufacturing method according to claim 11, wherein the second pattern portion includes dummy portions at both ends of each line in the plurality of lines.

20. A pattern formation method, comprising:
forming an electron beam resist film on a substrate;
patterning the electron beam resist film in an electron beam lithography process to form a pattern on the substate having a plurality of lines extending in a first direction, each line having a first width and being spaced from an adjacent line in the plurality of lines in a second direction intersecting the first direction by a least three times the first width and a second pattern portion extending in the second direction and spaced from ends of the plurality of lines in the first direction by twice or less the first width;
forming a conformal film on the patterned electron beam resist film, the conformal film having a thickness equal to the first width;
stripping the patterned electron beam resist film while leaving portions of the conformal film that were previously on sidewalls of the plurality of lines; and
etching the substrate using the portions of the conformal film as a mask.
